(19) United States
(12) Patent Application Publication
(10) Pub. No.: US 2026/0241315 A1
(43) Pub. Date: Aug. 20, 2026

(54) Integrated air cleaning blower and porous metal heat exchanger unit for data center immersion cooling systems

(71) Applicant: Richard P. Fennelly, Cortlandt Manor, NY (US)

(72) Inventor: Richard P. Fennelly, Cortlandt Manor, NY (US)

(73) Assignee: CoilPod LLC, Cortlandt Manor, NY (US)

(21) Appl. No.: 19/729,040

(22) Filed: Feb. 18, 2026

Related U.S. Application Data
(60) Provisional application No. 63/834,100, filed on Feb. 20, 2025.

(51) Int. Cl. B01D 45/16; H05K 7/20

(52) U.S. Cl. CPC B01D 45/16; H05K 7/20236; H05K 7/20263; H05K 7/20272

(57) ABSTRACT

An integrated air cleaning blower and porous metal heat exchanger unit for immersion cooling systems is disclosed. Heat generated by immersed electronic components is transferred to a secondary cooling fluid and conveyed to an external porous metal heat exchanger. An air cleaning blower, including a centrifugal particle separator, is positioned upstream of the porous metal heat exchanger to remove particulate matter from incoming ambient air before contact with the heat exchanger surface. A control and monitoring system may coordinate blower operation and detect performance degradation. The system reduces fouling, maintains heat transfer efficiency, and enhances reliability in data center immersion cooling applications employing secondary heat rejection loops.

### CROSS-REFERENCE TO RELATED APPLICATIONS

This application claims priority from U.S. Provisional Application No. 63/834,100, filed Feb. 20, 2025.

### FIELD OF THE INVENTION

The present invention relates generally to cooling systems for high-density electronic equipment. More particularly, the invention relates to immersion cooling systems for data centers and high-performance computing installations, preferably employing a secondary heat transfer loop, and an external porous metal heat exchanger component, and further integrating an air cleaning blower or centrifugal particle separator to mitigate particulate fouling of the external heat rejection component.

### BACKGROUND OF THE INVENTION

Immersion cooling systems are increasingly used to dissipate heat generated by high-density electronic components such as servers, GPUs, ASICs, and related computing hardware. In such systems, electronic components are immersed in a dielectric liquid that absorbs heat. The heated dielectric liquid transfers thermal energy, preferably to a secondary cooling loop, typically via a liquid-to-liquid heat exchanger located within or adjacent to the immersion tank. The secondary loop then conveys the heat to a remote or external heat rejection device located outside the building envelope. Some designs allow for a single loop to the external heat exchanger. Representative teachings to which the present invention is applicable can be found in U.S. Pat. Nos. 8,619,425, 9,713,290, 10, 225,958 and 10,667,427.

Recent immersion cooling systems, including those described in PCT Published Patent Application No. 2024/4089674 and other contemporary immersion cooling disclosures, illustrate the use of secondary fluid loops that transfer heat from immersion tanks to external dry coolers, radiators, or air-cooled heat exchangers positioned outdoors or otherwise exposed to ambient air. While such systems effectively transport heat outside the building, the external heat exchangers are typically exposed to atmospheric air containing dust, pollen, soot, sand, industrial particulates, and other airborne contaminants. When ambient air passes over or through conventional finned-tube or porous heat exchanger surfaces, particulate matter accumulates on the heat transfer surfaces. This fouling reduces airflow, increases pressure drop, diminishes heat transfer efficiency, and increases energy consumption. Over time, fouling necessitates cleaning, maintenance, and potential system downtime. U.S. Pat. No. 10,816,260 describes centrifugal particle separation devices, sometimes referred to as air cleaning blowers or centrifugal particle separators, which remove particulate matter from an air stream using centrifugal forces. U.S. Pat. No. 10,816,286 describes temperature escalation sensing and monitoring strategies that can detect performance degradation associated with fouling.

U.S. Pat. No. 11,026,344 describes advanced heat exchanger configurations suitable for efficient heat transfer. However, none of the known immersion cooling systems employing either a primary loop or secondary loops for external heat rejection disclose the integration of a porous metal heat exchanger with an upstream centrifugal particle separator configured as part of the enclosure or housing of the external heat rejection component.

Accordingly, there exists a need for an integrated system that reduces particulate fouling of an external porous metal heat exchanger used in connection with immersion cooling systems employing secondary heat transfer loops.

### SUMMARY OF THE INVENTION

The present invention provides an integrated air cleaning blower and porous metal heat exchanger unit for use in immersion cooling systems employing a heat transfer loop to reject heat outside a building.

In one aspect, the invention comprises an immersion cooling system including an immersion tank containing a dielectric cooling liquid for immersion of electronic components, a primary or primary-to-secondary liquid heat exchanger transferring heat from the dielectric liquid to an external porous metal heat exchanger configured to transfer heat from the secondary cooling fluid to ambient air.

In another aspect, the invention comprises an air cleaning blower, including either a non-motorized centrifugal particle separator or a motorized centrifugal particle separator, positioned upstream of the porous metal heat exchanger in the airflow path. The air cleaning blower removes particulate matter from incoming ambient air prior to contact with the porous metal heat exchanger.

In a further aspect, the invention includes an enclosure for the porous metal heat exchanger, wherein a conventional open or louvered cover is replaced with a cover containing one or more defined orifices. Each orifice is fitted with a centrifugal particle separator such that substantially all incoming ambient air is forced to pass through the separator before entering the heat exchanger enclosure.

In another aspect, the invention includes a control system configured to coordinate operation of the immersion cooling system, the secondary fluid loop (if present), and the air cleaning blower. The control system may dynamically adjust airflow rates, blower speeds, and secondary fluid flow rates based on cooling demand and environmental conditions.

In yet another aspect, the invention includes a monitoring system comprising one or more sensors configured to monitor temperature escalation at the porous metal heat exchanger, airflow reduction, electrical consumption of the overall immersion cooling system, and particulate concentration in the incoming air. The monitoring system can generate maintenance alerts when performance degradation exceeds a predetermined threshold.

The integration of centrifugal particle separation with a porous metal heat exchanger in an immersion cooling architecture reduces fouling, maintains heat transfer efficiency, reduces energy consumption, and extends service intervals.

### DETAILED DESCRIPTION OF THE INVENTION

An immersion cooling system includes at least one immersion tank containing a dielectric liquid in which electronic components are submerged. Heat generated by the electronic components is absorbed by the dielectric liquid. The heated dielectric liquid is circulated through a primary or primary-to-secondary liquid heat exchanger, transferring heat to a secondary cooling fluid.

The secondary cooling fluid circulates through a closed secondary loop extending to an external heat rejection unit positioned outside the building or otherwise exposed to ambient air. The external heat rejection unit includes a porous metal heat exchanger core. The porous metal heat exchanger may comprise sintered metal structures, metal foam, expanded metal matrices, or other high-surface-area metallic porous media providing enhanced convective heat transfer between the secondary cooling fluid and ambient air.

The porous metal heat exchanger is enclosed within a housing. In conventional systems, the housing includes open grilles or louvers allowing unrestricted ambient airflow. In the present invention, the housing cover is reconfigured to include one or more defined orifices. Each orifice is fitted with a centrifugal particle separator.

The centrifugal particle separator may be non-motorized, relying on induced airflow from system fans, or motorized to provide active airflow generation. The separator imparts a rotational motion to incoming air, causing heavier particulate matter to migrate radially outward under centrifugal force. The separated particulates are discharged or collected, while cleaned air continues downstream into the enclosure and across the porous metal heat exchanger core.

By ensuring that substantially all incoming air passes through the centrifugal particle separator, the invention significantly reduces deposition of dust and debris within the porous metal structure. This is particularly advantageous for porous metal heat exchangers, which possess high surface area and interconnected pore networks that would otherwise be susceptible to clogging.

The control system may include a programmable controller in communication with temperature sensors mounted on or within the porous metal heat exchanger, airflow sensors measuring volumetric flow rate through the enclosure, particulate sensors positioned upstream of the separator, and power monitoring sensors measuring total system electrical consumption.

In one embodiment, a temperature escalation sensor is attached to the porous metal heat exchanger coils or core. If the temperature differential between the secondary fluid inlet and outlet exceeds a predetermined threshold indicative of fouling, the control system may increase blower speed or generate a maintenance alert.

Airflow sensors may detect gradual reduction in airflow caused by partial blockage. Electrical consumption monitoring may detect increased fan or pump power associated with increased pressure drop. A visual monitoring device may provide optical assessment of fouling accumulation.

The control system may dynamically adjust blower operation based on ambient particulate levels. During periods of elevated dust concentration, blower speed or separator operation may be increased. During low particulate conditions, energy consumption may be reduced.

The invention is particularly suited for data centers, cryptocurrency mining facilities, artificial intelligence computing clusters, and other high-density computing installations where immersion cooling systems employ secondary loops to transfer heat to external air-cooled heat exchangers.

1. An integrated cooling system for immersion-cooled electronic equipment comprising: an immersion tank containing a dielectric liquid configured to absorb heat from electronic components; a heat exchanger configured to transfer heat from the dielectric liquid to an external heat rejection unit; a porous metal heat exchanger disposed in the external heat rejection unit and configured to transfer heat from the secondary cooling fluid to ambient air; and an air cleaning blower positioned upstream of the porous metal heat exchanger and configured to remove particulate matter from an air stream before the air stream contacts the porous metal heat exchanger.

2. The system of claim 1, wherein the air cleaning blower comprises a centrifugal particle separator.

3. The system of claim 2, wherein the centrifugal particle separator is non-motorized.

4. The system of claim 2, wherein the centrifugal particle separator is motorized and includes a controllable drive motor.

5. The system of claim 1, wherein the porous metal heat exchanger comprises a sintered metal or metal foam structure providing interconnected porosity for enhanced heat transfer.

6. The system of claim 1, further comprising an enclosure housing the porous metal heat exchanger, the enclosure including a cover having one or more orifices, each orifice being fitted with a centrifugal particle separator so that substantially all incoming air passes through the separator before entering the enclosure.

7. The system of claim 1, that further comprises a control system configured to coordinate operation of the air cleaning blower and flow of the secondary cooling fluid.

8. The system of claim 7, wherein the control system dynamically adjusts blower speed based on cooling demand and ambient particulate conditions.

9. The system of claim 1, that further comprises a monitoring system including at least one temperature sensor mounted to the porous metal heat exchanger and configured to detect temperature escalation indicative of fouling.

10. A method for improving heat rejection efficiency in an immersion cooling system employing a secondary heat transfer loop, comprising: transferring heat from a dielectric immersion fluid to a secondary cooling fluid; circulating the secondary cooling fluid to an external porous metal heat exchanger; directing ambient air through a centrifugal particle separator to remove particulate matter; and passing the cleaned air over the porous metal heat exchanger to transfer heat from the secondary cooling fluid to the ambient air.
